(19) United States
(12) Patent Application Publication
(10) Pub. No.: US 2015/0061496 A1
(43) Pub. Date: Mar. 5, 2015

(54) System for Generating High Speed Flow of an Ionized Gas

(71) Applicant: Mectron Engineering Company, Saline, MI (US)

(72) Inventors: James L. Hanna, Saline, MI (US); Glenn D. Gram, Saline, MI (US)

(21) Appl. No.: 14/460,711

(22) Filed: Aug. 15, 2014

Related U.S. Application Data
(63) Continuation-in-part of application No. PCT/US2013/058218, filed on Sep. 5, 2013.

(51) Int. Cl. H01J 37/32; H01J 37/24; H01J 37/08

(52) U.S. Cl. CPC H01J 37/3211; H01J 37/08; H01J 37/241; H01J 37/3244
USPC 315/111.81

(57) ABSTRACT

The invention relates to a system for generating an ion stream which may be useful for various applications. In one application, the ion stream may be used to excite nano-spheres. In another application, the ion stream may be used for sterilization and therapy in accordance with the teachings of the invention.

### RELATED APPLICATION

The present patent document is a Continuation-in-Part application and claims the benefit of the filing date under 35 U.S.C. §119(e) of Provisional U.S. Patent Application Ser. No. 61/697,391, filed Sep. 6, 2012, and PCT International Application No. PCT/US13/058218, filed Sep. 5, 2013, which is hereby incorporated by reference.

### FIELD OF THE INVENTION

This invention relates to a system for generating a high speed flow of ions.

### BACKGROUND AND SUMMARY OF THE INVENTION

This invention relates to a system for generating a high speed ion flow which is useful for various applications. In one application, the high speed ion flow is used to excite nano-spheres of different metals such as silver, gold, platinum, etc. causing them to vibrate at a high frequency based on inherent properties of the element in a medium. One application for the technology is to inject nano-spheres of a certain type metal into a tumor of a human patient or animal. The externally applied high speed ion flow can be used to excite and heat the in-situ nano-spheres that will increase their temperature and destroy the tumor cells (or other tissue).

The system in accordance with this invention can be tuned to the characteristic frequencies of various elements such as gold, platinum, silver, etc. The high speed ion flow may be used for various medical or industrial purposes, for example in addition to the above-mentioned application, the ion stream may have the ability to sterilize surfaces and treat surfaces for various purposes. Ion system can be used to increase the surface wettability in seeds to make them germinate quicker. Another application is in surface treatment to clean plastics and metals and increase their surface wettability for applying coatings and glues.

### BRIEF DESCRIPTION OF THE DRAWINGS

FIG. 1 is a pictorial view of the ion generating system in accordance with the present invention;

FIG. 2 is an illustration of a ion source system that is used in an ion generating system;

FIG. 3 is a detail view of a nozzle for a ion source system that is used in an ion generating system;

FIG. 4A is a circuit diagram of driver electronics that is applied in an ion generating system;

FIG. 4B is a continuation of the circuit diagram of 4a that is applied in the ion generating system.

### DETAILED DESCRIPTION OF THE INVENTION

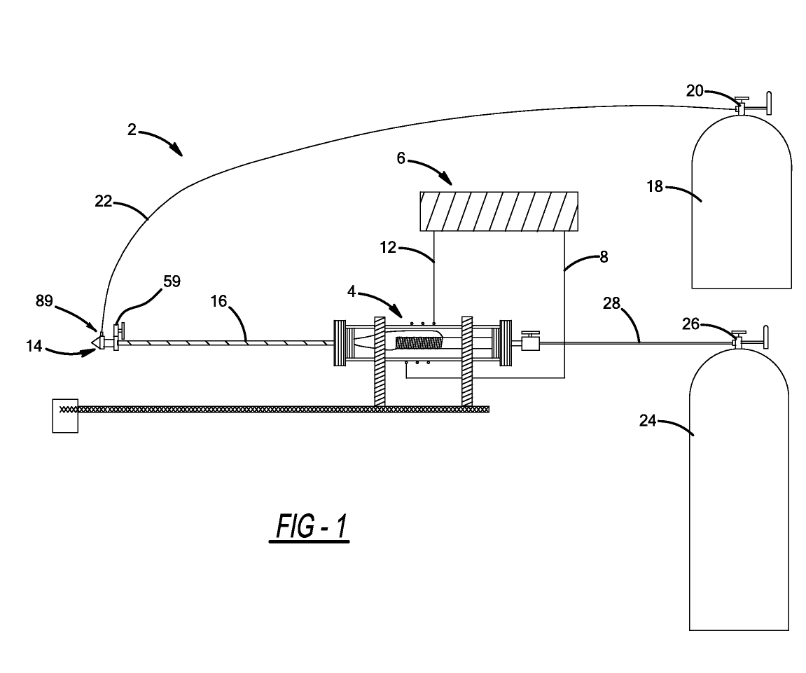

FIG. 1 illustrates an ion generating system 2 in accordance with the present invention. The ion generating system 2 includes two primary systems, including an ion source system 4 and driver electronics 6. The driver electronics 6 are designed to generate a high frequency alternating current (AC) at a range of frequencies. The driver electronics 6 drive a custom designed transformer implemented in the ion source system 2. The driver electronics 6 are electronically connected with the ion source system via first primary coil conductors 8 and 12.

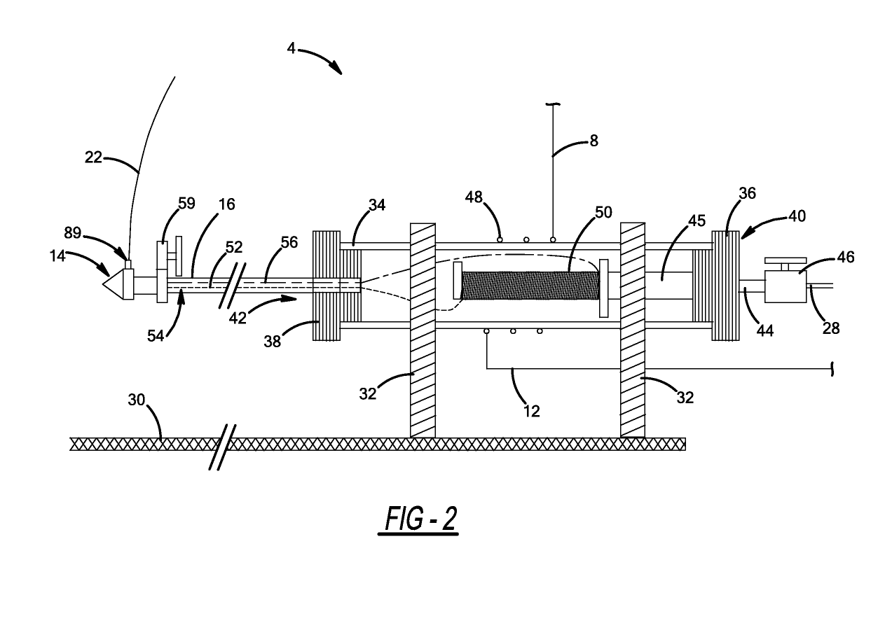

FIG. 2 illustrates the ion source system 4 which includes a nozzle 14 operably coupled to the ion source system 4 via a conduit 16. The nozzle 14 is configured to emit a high speed ion discharge from an ion outlet. The conduit 16 supplies high voltage power generated in a secondary coil 50 of the custom designed transformer to achieve ion production in the nozzle 14. When a high voltage charge builds in the nozzle, a flow of ionized gas is used to generate the high speed flow of ions. In some implementations the high speed ion flow may be of an ionized helium gas. The conduit 16 includes a flexible conduit that enables the nozzle 14 to be selectively positioned to direct the ion gas discharge toward a target. The conduit 16 is preferably constructed of Mu-metal. The conduit 16 serves to limit electromagnetic radiation from passing into the environment surrounding the ion source system 4.

In operation, the gas is energized to create a high speed flow of ionized gas, for example helium gas, is discharged from an ion gas supply 18 shown in FIG. 1 through a first flow valve 20. The ion gas supply may be stored in a compressed gas tank. The first flow valve 20 controls the flow rate of the ion gas into the ion gas supply line 22. The ion gas supply line 22 is in fluid communication with the nozzle 14 and provides a controlled flow of the ion gas to the nozzle 14.

Upon entry into the nozzle 14, the ion generation gas is ionized in response to a high frequency/high voltage electric field in the nozzle 14. A discharge of a high speed ionized gas from the nozzle 14 is formed into a stream of ionized gas. The stream of ions oscillates at a frequency corresponding to the high frequency field in the nozzle 14. The high frequency/high voltage field causes the stream of ionized gas to oscillate at a frequency corresponding to the excitation of ionization of the ionized generation gas. In some embodiments of the invention, the oscillating frequency of ionized particles of the ion flow is configured to oscillate at a natural frequency of a material or substance, for example a metallic substance or solution thereof.

In some embodiments of the invention, a dielectric gas, for example nitrogen, is supplied to the ion system 4 shown in FIG. 2, through the custom designed transformer, and through the conduit 16 to purge atmospheric air from the ion source system 4. The dielectric gas serves to limit a possibility of arcing in the windings of the custom designed transformer and along the length of the conduit 16. The dielectric gas is fed into the ion source system from a dielectric gas supply 24 in FIG. 1. Though referred to as a dielectric gas, the dielectric gas may include any inert or electrically insulating gas, compound, or other electrically insulating gases, for example nitrogen. The dielectric gas is supplied to the ion source system through a second flow valve 26. The second flow valve 26 allows a controlled flow of the dielectric gas to pass through a dielectric gas supply line 28 to limit a potential of arcing in the ion source system 4 in FIG. 2.

FIG. 2 illustrates an example of an ion source system 4 used in the ion generating system 2 in FIG. 1 in accordance with the present invention. The ion source system 4 as shown in FIG. 2 is conveniently mounted on a baseplate 30 with a pair of upwardly extending structural supports 32. The upwardly extending supports 32 mount to a tube 34. In various embodiments, the tube 34 is formed of any electrically insulating material.

In FIG. 2, the tube 34 is closed by a pair of end caps defining a first end cap 36 and a second end cap 38. The first end cap 36 closes the tube 34 at a proximal end 40 and the second end cap closes the tube 34 at a distal end 42. The first end cap 36 and the second end cap 38 are preferably of an electrically insulating material. Affixed to the first end cap 36 is an inlet nipple 44 which is attached to an inlet valve 46 and the dielectric gas supply line 28. The inlet nipple 44 is configured to allow a flow of the dielectric gas to enter the glass tube. The conduit 16 is affixed to the second end cap 38 and extends to the nozzle 14.

In FIG. 2 the center tube 45 is affixed to the first end cap 36 and extends along a central axis of tube 34. The center tube 45 forms a flow path for the dielectric gas to enter the tube 34 through the inlet nipple 44 and the first end cap 36. The dielectric gas from the dielectric gas supply 24 (FIG. 1) flows through the dielectric gas supply line 28, the inlet nipple 44 (FIG. 2), and the inlet valve 46 and into the tube 34 through center tube 45. The center tube 45 is preferably of a non-conductive material, such as plastic. The first end cap 36 positions the center tube 45 within an interior cavity of the tube 34.

In FIG. 2 the ion source system 4 is electrically excited through the driver electronics 6. The driver electronics include an AC drive system for a custom designed transformer system. A primary coil 48 shown in FIG. 2 is wrapped around the outside of the tube 34 and is electrically coupled to the driver electronics 6 via the first primary coil conductors 8 and 12. In a preferred embodiment of the invention, the primary coil 48 includes small number of turns of 4 mm diameter copper tubing uniformly wrapped around a central portion of the length of the outside of the tube 34.

As shown in FIG. 2, secondary coil 50 of the custom designed transformer system includes windings wrapped around the outside of the center tube 45. The number of turns in the secondary coil 50 may vary substantially based on a target frequency of the high frequency field. The target frequency of the high frequency field corresponds to a switching frequency induced in the secondary coil 50. In a preferred embodiment of the invention, the secondary coil 50 includes a large number of turns of enameled copper wire uniformly wrapped closely together around the center tube 45. The center tube 45 and the secondary coil 50 may also be interchangeable. In embodiments having interchangeable secondary windings, the secondary windings may be changed by removing the first end cap 36 to access the center tube 45.

As shown in FIG. 2, secondary coil 50 is wound around the center tube 45 and the windings should be in the middle of the center tube 45. The first end of the secondary coil 50 is conductively connected to a first supply wire 52 that extends through the second end cap 38 through an internal passage 54 of the conduit 16. The second end of the secondary coil 50 is conductively connected to a second supply wire 56 that also extends through the second end cap 38 through an internal passage 54 of the conduit 16. In accordance with the custom transformer design, the turn's ratio between the primary coil 48 and the secondary coil 50 is very great, and the system is driven at high frequency. These systems are capable of providing extremely high voltage outputs from their secondary windings.

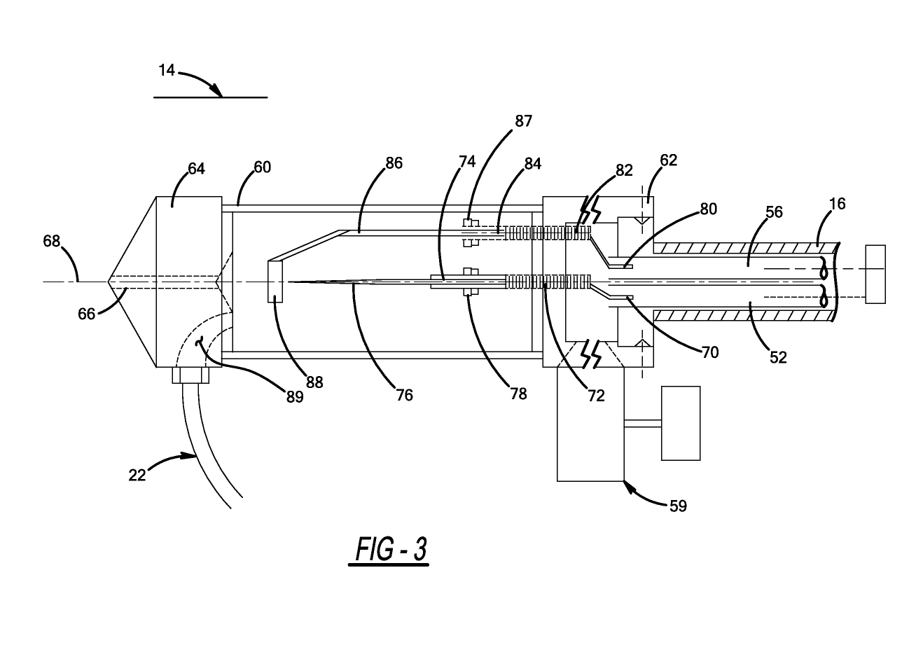

As shown in FIG. 2, the first supply wire 52 extends from a first end of the secondary coil 50 through the internal passage 54 of the conduit and into the nozzle 14. The first supply wire 52 is conductively connected to a conductive rod 76 of conductive material positioned in the nozzle 14 as shown in FIG. 3. The conductive rod 76 is configured to provide a conductive path that passes energy to a ring 88 located proximate to the conductive rod in the nozzle 14.

As shown in FIG. 3, the ring 88 is conductively connected to the second supply wire 56. The second supply wire 56 extends back through the internal passage 54 of the conduit 16 and into the tube 34. The second supply wire 56 extends through the tube where the second supply wire 56 is conductively connected to the second end of the secondary coil 50. As the current oscillates through the secondary coil 50, electrical potential energy fluctuates between the ring and the needle, generating a high frequency/high voltage electromagnetic field. Each of the first supply wire 52 and the second supply wire 56 consist of wires configured to transport high voltage from the secondary coil to the nozzle. The first supply wire 52 and the second supply wire 56 may include heavy insulation and a core of conductive heavy gauge stranded wire.

The passage from the inlet nipple 44 through the end of the tube 45, through the internal passage 54 of the conduit 16, and into the nozzle 14 forms a sealed passage for the flow of the dielectric gas from the dielectric gas supply 24. As a safety precaution, prior to activation of the driver electronics 6, the inlet valve 46 may be opened and the second flow valve 26 may be adjusted to allow a flow of the dielectric gas to enter the tube 45. The dielectric gas displaces atmospheric air from the tube 45 into tube 34 and then passes into the internal passage 54 of the conduit 16. The dielectric gas displaces atmospheric air from the internal passage 54 of the conduit 16 and exit through a purge valve 59 connected to the nozzle 14 proximate the connection of the conduit 16 and the nozzle 14. The dielectric gas may continue to flow through the tube 34 and the internal passage 54 of the conduit during operation to limit the potential of arcing in the ion source system 4. In some cases, the dielectric gas may also be sealed in the ion source system by closing the purge valve 59 after the atmospheric air is displaced.

FIG. 3 illustrates a detail view of the nozzle 14 for the ion source system 4 in accordance with the present invention. The nozzle 14 generally includes a nozzle chamber 60, a nozzle inlet 62, and a nozzle tip 64. A distal end of the conduit 16, opposite the end connected to the second end cap 38 of the ion source system 4, is connected to the nozzle inlet 62. The nozzle tip 64 includes an ion outlet 66 forming an outlet passage from the nozzle chamber 60 to a region outside the nozzle. The nozzle outlet 66 extends along a longitudinal axis 68 of the nozzle 14. The nozzle chamber 60 may be of an electrically insulating and flame retardant material. The nozzle inlet 62 and the nozzle outlet 64 may be of an electrically insulating and flame retardant material.

To transfer current from the secondary coil 50, the first supply wire 52 is conductively connected to a first terminal 70 shown in FIG. 3. The first terminal 70 is conductively connected to a first stud 72. The first stud 72 may be of a conductive metal and is threaded through an opening in the nozzle inlet 62. The first stud 72 is generally aligned with the longitudinal axis 68 of the nozzle 14. At one end, the first stud 72 forms a first internal cavity 74 configured to receive the conductive rod 76. The conductive rod 76 is needle-like in shape and be of a thermally resistant, electrically conductive material. The conductive rod 76 is affixed in the first internal cavity 74 of the first stud 72 by a collet 78.

With continued reference to FIG. 3, the second supply wire 56 is conductively connected to a second terminal 80. The second terminal 80 is conductively connected to a second stud 82. The second stud 82 may be of a conductive metal and is threaded through an opening in the nozzle inlet 62. The second stud 82 is offset from and parallel to longitudinal axis 68 of the nozzle 14. At one end, the second stud 82 forms a second internal cavity 84 configured to receive a conductive ring assembly 86. The conductive ring assembly 86 extends parallel to the conductive rod 76 and includes a ring 88 aligned with the conductive rod 76. The ring 88 is aligned with the conductive rod 76 such that the longitudinal axis 68 of the nozzle 14 and a corresponding longitudinal axis of the conductive rod 76 pass centrally through an opening inside the ring 88. The conductive ring assembly 86 is affixed in the second internal cavity 84 of the second stud 82 by a collet 87. The conductive ring assembly 86 may be of a thermally resistant, electrically conductive material.

In operation, an ion generation gas, such as helium, flows into the nozzle from the ion gas supply 18 through an ion gas inlet 89. The flow of the ion generation gas is regulated by the first flow valve 20 and flows through the ion gas supply line 22. The ion generation gas passes into the nozzle chamber 60 and is acted upon by the high frequency/high voltage field produced by the secondary coil 50. The high frequency/high voltage field is transmitted into the nozzle chamber 60 alternately via the first supply wire 52 and the second supply wire 56. The alternating current in the secondary coil conducted through the first and second supply wires 52 and 56 causes the electrical potential energy to fluctuate between the ring 88 and the conductive rod 76, generating the high frequency/high voltage field.

Referring to FIG. 3, the high frequency/high voltage field passes between the conductive rod 76 and the ring 88. As the ion generation gas passes through the high frequency/high voltage field, the ion generation gas is ionized, thereby generating an ion stream which is emitted from the ion outlet 66. The ion stream may be defined as a micro-stream of ions capable of delivering charged ions to a target region. Generally, the ion stream may have multiple uses with one potential use being described as follows.

There are certain treatment situations for human and animal patients in which is desired to induce high temperatures in tissues which can lead to the destruction of cell membranes and therefore undesired cells and tissues, referred to generically as hyperthermia treatment. In one such therapeutic application, nano-spheres of gold, silver or other metals which can be homogeneous or in the form of coated nano-spheres can be introduced into tissues. This can be accomplished by direct injection or through a form of tissue or organ selective delivery systems. When the nano-spheres are accumulated within the desired target tissue the nano-spheres can be excited externally by applying the ion source in accordance with this invention. This excitation causes them to vibrate at a very high frequency which leads to a heating effect.

It is contemplated that nano-spheres of various sizes may be used. The excitation of the nano-spheres is accomplished by amplitude modulation of the field applied to the gas stream at a desired frequency. In some embodiments, the ion stream may be used without the excitation of nano-spheres for many applications including sterilization of items and surfaces, augmenting wound healing, and for dental applications.

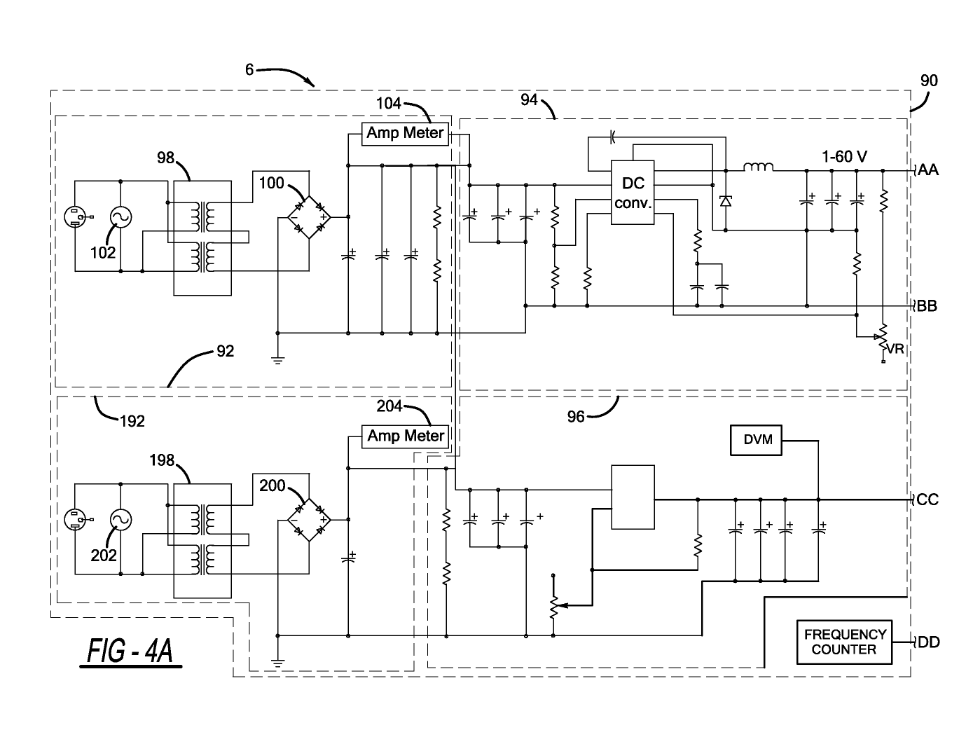

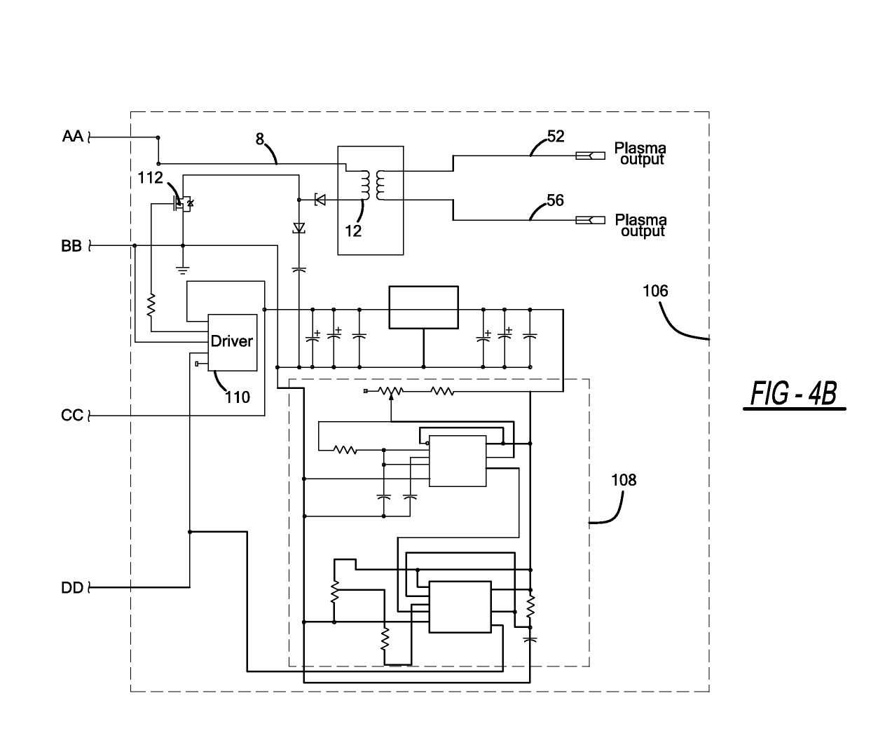

FIG. 4A illustrates driver electronics 6 applied in the ion generating system 2 in accordance with the invention. The driver electronics 6 includes various electrical components and topographies configured to drive the primary coil 48 at a controlled voltage and frequency. The various circuits and components described herein may be substituted with a variety of similar components and alternate methods for generating a high frequency driving current similar to those disclosed herein.

As shown in FIG. 4A, in one preferred embodiment, the driver electronics 6 include a power supply 90 comprising two AC to DC converters 92 and 192, a first DC voltage converter 94, and a second DC voltage converter 96. The first and second AC to DC converters 92 and 192 includes step down transformers 98 and 198 and two bridge rectifiers 100 and 200. Current from the AC inputs 102 and 202, such as 60 Hz line current with a 250VA capacity, as inputs are conducted through the two step down transformers 98 and 198. The current passing through the two step down transformers 98 and 198 is rectified by the bridge rectifiers 100 and 200 to produce the DC outputs. For operating safety and the protection of the driver electronics 6, an amp meter 104 may be placed in line with the DC voltage output from the AC to DC converter 92 to monitor the current delivered to the driver electronics 94.

The first DC voltage converter 94 uses a buck-boost converter. The second DC voltage converter 96 uses a linear voltage regulator. The first DC voltage converter 94 is configured to deliver power to the primary coil 48. In this particular embodiment, as shown FIG. 4A, the first DC voltage converter 94 is operable to output voltage ranging from approximately 1 to 60 Volts. The voltage output is preferably set to a voltage output ranging from 20 to 45 Volts. The voltage supplied and specific power requirements for the primary coil 48 depend on a variety of design variables including the design of the primary and secondary coils 48 and 50, the insulation of various components of the ion source system 4, and a desired intensity of a generated ion stream.

Referring now to FIG. 4B, a continuation of the circuit diagram of FIG. 4a is shown in accordance with the invention. The second DC voltage converter 96 is configured to deliver supply power to a plurality of control and timing components 108. The control and timing components include a timer 108, a high-speed transistor driver 110, and a FET 112. The timer 108 is configurable to generate a timing signal at a variety of frequencies. For example, a frequency of the timing signal may range from 10 kHz to 3 MHz. In a preferred embodiment, the frequency of the timing signal ranges from 100 kHz and 3 MHz, and in some cases is configured to operate at a range of frequencies from 400 kHz and 4 MHz. The frequency of the timing signal may vary among the ranges described herein and is dependent on the specific design of the ion source system 4, for example, the specific configuration of the primary coil 48, the secondary coil 50, and a desired intensity of a generated ion stream.

As further shown in FIG. 4B, the timer 108 is operably coupled to the FET driver 110 and communicates the timing signal to the FET driver 110. The FET driver 110 includes any transistor driver operable to achieve a desired frequency and voltage in response to the timing signal and is preferably capable of managing high sink/source currents, for example current in excess of 10 Amps. In a preferred embodiment of the invention, the FET driver is a power FET driver operable to achieve switching speeds corresponding to the ranges of the timing signal.

The FET driver 110 is operably coupled to the FET 112. The FET 112 may include a variety of devices configured to generate an electrical switching signal. The FET 112 is preferably operable to achieve switching speeds corresponding to the ranges of the timing signal previously described. The FET 112 is supplied power from the first DC voltage converter 94. In operation, the FET 112 generates an output signal with a frequency corresponding to the timing signal from the timer 108. The voltage of the output signal varies in response to the voltage supplied from the first DC voltage converter 94.

With continued reference to FIG. 4B, the output signal from the FET 112 is conducted through the first primary coil conductor 8 and into the primary coil 48 at a first primary coil end. To complete the circuit of the primary coil, the second primary coil conductor 12 is connected to a second primary coil end and returns to output voltage of power supply 94 of the driver electronics 6. The frequency of the output signal from the FET 112 induces an electromagnetic field having varying magnetic flux. The varying magnetic flux induces a voltage in the secondary coil 50. The voltage induced in the secondary coil 50 may be applied to generate the high frequency/high voltage field which is transmitted into the nozzle chamber 60 to generate the ion stream.

The frequency of the high frequency field used to generate the ion stream is a function of the configuration of the secondary coil 50. As such, in an exemplary embodiment, the secondary coil 50. The secondary coil that is discussed herein can be changed out for other secondary coils 50 of different amount of windings and wire gauges to change the frequency and voltage they will be used for.

The different frequencies are applied to generate ion streams oscillating at different frequencies. The different frequencies of the ion flow may be operable to excite different materials, for example nano-spheres of gold, silver or other metals which can be homogeneous or in the form of coated nano-spheres. Though heating of nano-spheres is discussed herein, the applications of the high speed ion streams generated at different frequencies provides for numerous applications for sterilization and therapy in accordance with the teachings of the invention.

Some applications of the ion generating system may include using an ion stream to sterilize items and surfaces, augmenting wound healing, and for dental applications. In one particular application, nano-spheres of gold, silver or other metals which can be homogeneous or in the form of coated nano-spheres can be introduced into tissue that is targeted for treatment. The delivery of the nano-spheres may be completed through injection into the tissue. When the nano-spheres are accumulated within the desired target tissue the spheres can be excited externally by applying the ion source in accordance with this invention.

The ion stream may be delivered from the nozzle of the ion source system and pass through tissue surrounding the injection site without affecting the tissue. Upon reaching the desired target tissue, the ion stream may induce high temperatures in the tissue which may provide for hypothermic treatment of the tissue. The excitation of the nano-spheres in response to the ion stream causes them to vibrate at a very high frequency which leads to a heating effect.

While the present invention has been described with reference to specific exemplary embodiments, it will be evident that various modifications and changes may be made to these embodiments without departing from the broader scope of the invention as set forth in the claims. Accordingly, the specification and drawings are to be regarded in an illustrative rather than a restrictive sense.

What is claimed is:

1. An ion generating system comprising:
driver electronics for generating an AC supply;
an ion source system including a primary coil connected to the driver electronics, a secondary coil coaxially positioned within the primary coil, and conductive connectors connected to the secondary coil;
a conduit having a first end extending from the ion generating system, and conductive connections passing from the secondary coil through an internal passage of the conduit;
a nozzle affixed to a second end of the conduit, and
a gas source supplying gas to an inlet end of the nozzle, gas flowing into the nozzle ionized while passing through the nozzle and outward through an outlet end of the nozzle under the influence of an electric field produced by the secondary coil, the electric field transferred into the nozzle via the conductive connector.

2. The system according to claim 1, wherein the secondary coil is configured to generate a frequency and voltage configured to oscillate at a natural frequency of a metallic substance in a medium.

3. The system according to claim 1, wherein the conductive connector comprises a first and second supply wire, the first and second supply wire conductively connected to a first end of the secondary coil.

4. The system according to claim 3, wherein the nozzle comprises a conductive rod conductively connected to a second end of the first supply wire.

5. The system according to claim 4, wherein the nozzle comprises a ring aligned with the conductive rod such that a longitudinal axis of the conductive rod passes centrally through an opening inside the ring.

6. The system according to claim 5, wherein the conductive rod is needle like in shape with the narrow end of the needle-like shape extending toward the ring.

7. The system according to claim 5, wherein the ring is connected to a second supply wire, the second supply wire extending from the nozzle to a second end of the primary coil through the internal passage of the conduit.

8. The system according to claim 5, wherein the gas flowing into the nozzle is ionized by passing through the electromagnetic field of the secondary coil emitted from the conductive rod to the ring.

9. A method for generating a targeted ion stream, the method comprising:
generating an AC supply in driver electronics, the driver electronics configured to control a driving frequency and voltage of a FET to control the AC supply,
conducting the AC supply in a primary coil to generate an electromagnetic field at the driving frequency, inducing a current in a secondary coil in response to the electromagnetic field, the current in the secondary coil comprising a high voltage signal, the high voltage signal oscillating at a frequency corresponding to the configuration of the secondary coil,
transmitting the high voltage signal through a conduit to a nozzle, the high voltage signal conducted through a conductive connector,
inducing a flow of gas through the nozzle, and
generating an ion stream in response to the high voltage signal in the gas flowing through the nozzle.

10. The method according to claim 9, wherein the driving frequency is between 100 kHz and 4 MHz.

11. The method according to claim 9, wherein the driving frequency is controlled by a timer and the FET of the driver electronics.

12. The method according to claim 14, wherein the number of turns in the secondary coil is configurable by changing the secondary coil to control the frequency and voltage.

13. The method according to claim 15, wherein a secondary coil will correspond to a natural frequency of a material.

14. An ion generating device comprising;
driver electronics for generating an AC supply,
an ion source system including a primary coil and a secondary coil, the secondary coil positioned within the primary coil, the primary coil conductively connected to the driver electronics, a conduit connected to a first end of the ion source system, the conduit comprising an internal passage, a conductive connector passing from the secondary coil through the internal passage, the conductive connector configured to transfer a high voltage/high frequency signal from the secondary coil through the 2 supply wires, a first end of the conduit attached to an end cap of the first tube,
a nozzle, the nozzle affixed to a second end of the conduit, the nozzle configured to receive the 2 supply wires, one supply wire conductively connected to a conductive rod, the conductive rod extending along a longitudinal axis of the nozzle, the other supply wire is conductively connected to a conductive ring, and
a gas source supplying gas to the nozzle, gas flowing into the nozzle ionized while passing in proximity to the conductive rod and outward through an outlet end of the nozzle to produce an ion stream in response to an electric field, the electric field produced by the secondary coil and conducted through the conductive rod.

15. The device according to claim 14, wherein an oscillating of an ionized charge of the ion gas stream corresponds to a natural frequency of the metallic substance.
